(19) United States
(12) Patent Application Publication
(10) Pub. No.: US 2022/0213610 A1
(43) Pub. Date: Jul. 7, 2022

(54) PHOTORESIST RESOLUTION CAPABILITIES BY COPPER ELECTROPLATING ANISOTROPICALLY

(71) Applicant: Rohm and Haas Electronic Materials LLC, Marlborough, MA (US)

(72) Inventors: Alejo M. Lifschitz Arribio, Waltham, MA (US); Alexander Zielinski, Charlton, MA (US); Samer Hammoodi, Worcester, MA (US); Joseph F. Lachowski, Sutton, MA (US); Michael K. Gallagher, Hopkinton, MA (US); Curtis Williamson, Cambridge, MA (US); Jonathan D. Prange, Lincoln, MA (US)

(21) Appl. No.: 17/564,810

(22) Filed: Dec. 29, 2021

Related U.S. Application Data
(60) Provisional application No. 63/134,348, filed on Jan. 6, 2021.

(51) Int. Cl. C25D 5/00; C25D 7/12; C25D 3/38; G03F 7/20; C25D 5/02

(52) U.S. Cl. CPC C25D 5/605; C25D 7/123; C25D 5/02; G03F 7/20; C25D 3/38

(57) ABSTRACT

Features of substrates are copper electroplated by a method which involves copper electroplating selectively deposited seed layers or seed layers of photoresist defined features with a copper electroplating composition containing select suppressor compounds and select leveler compounds which enable anisotropic plating. Optionally, the seed layers can be treated with an aqueous solution of sulfur containing accelerators prior to copper electroplating.

### FIELD OF THE INVENTION

The present invention is directed to a method of improving photoresist resolution capabilities by copper electroplating anisotropically of photoresist defined features. More specifically, the present invention is directed to a method of improving photoresist resolution capabilities by copper electroplating anisotropically of photoresist defined features by copper electroplating anisotropically seed layers of the photoresist defined features of the substrate with an aqueous copper electroplating composition containing select suppressors and select leveler compounds which enable copper electroplating anisotropically, wherein the seed layers of the photoresist defined features can be optionally treated with a solution of sulfur containing accelerator compounds prior to copper electroplating anisotropically of the seed layers.

### BACKGROUND OF THE INVENTION

Packaging and interconnection of electronic components relies on the ability to create a circuit pattern within a dielectric matrix and fill that pattern with a metal that transmits electrical signals, such as copper. Traditionally, these circuits are built through a photoresist pattern, wherein the process of exposure through a patterned mask, and subsequent removal of the exposed material, leads to the formation of a network of recessed, empty features over a conductive seed. These features can be filled with copper by electroplating over the seed such that, after photoresist removal and etch-back of the seed, conductor patterns are obtained. Features in these circuits typically include lines, pads, vias, pillars, and through-holes of various dimensions.

Control of fill uniformity and deposit quality is typically achieved using plating bath additives that interact with the electroplated deposit as it grows. While the additives tailor many of the microstructure properties of the deposit, the shape of the plated feature itself is controlled solely by the photoresist. In other words, the photoresist contains the copper deposit as it is growing and prevents it from taking any shape other than that of the circuit pattern. If the deposit were to grow above the height of the photoresist, then it is expected that the shape will not be retained with fidelity. In most cases, copper will continue to plate over the photoresist in all directions, a behavior that is referred to as isotropic plating growth. This multidirectional expansion compromises the integrity of the circuit, for example, by joining adjacent features and creating circuit shorts that render the whole architecture useless. As a result, in most industrial plating processes, the photoresist or patterning layer is required to be at least as thick as the target plated deposit height.

In practical terms, the photoresist used for packaging circuits needs to be even taller than the feature itself to avoid issues of circuit bridging as we try to level plating over very different feature heights. Since modern circuits include both small and large openings in the photoresist that have different diffusion constraints for the levelling additives, we find that reaching the target height for 1 size might mean that we need to plate the other size significantly taller. This is particularly true for high-frequency and high-power applications, where finer lines for data transmission are integrated with larger features that provide increasing amounts of power to the denser components. Thus, present and future applications will continue to exacerbate the need to increase the need to image finer features in relatively thicker photoresist layers.

These trends, borne out of the natural limitations of plating technologies, result in dramatic technical and economic limitations on the manufacture of circuits. Specifically, the need to fully contain the plated features and account for levelling issues will push the resolution limit of photoresist, photoimageable materials, and imaging tools. For 2 μm lines and spaces (L/S) dimensions, conventional photoresist materials are not able to form trenches deeper than 6 μm at an industrial scale. Chemically-amplified photoresist can push the trench depth to 10 μm, but this comes at the expense of increasing the imageable material cost by more than 2 orders of magnitude.

It would thus be advantageous to develop new circuit plating protocols that allow one to operate with photoresist that is thinner than the intended feature height, but which nevertheless is able to sustain the pattern shape throughout the feature heights. Doing so would not only increase resolution or enable greater circuit design flexibility, but it would also reduce material costs for the patterning layer by simply reducing the volume of photoresist involved in the process.

To enable such a process, metal plating technologies need to be re-engineered so that plated film growth occurs anisotropically in the direction perpendicular to the substrate. This is unlike current processes, where any deposit unconstrained by the patterning layer will grow in several directions simultaneously due to natural electric field distribution.

Accordingly, there is a need for a method of anisotropically electroplating copper for forming photoresist defined features.

### SUMMARY OF THE INVENTION

The present invention is directed to a method comprising:

a) providing a substrate comprising a seed layer;
b) optionally selectively applying an aqueous treatment solution comprising a sulfur containing accelerator to the seed layer, wherein a pH of the aqueous treatment solution is 3 and below, or 9 and above;
c) providing a copper electroplating composition comprising a source of copper ions, an accelerator, an acid, a source of chloride, a suppressor which generates an α-peak curve in a cathode wave of a voltammogram of the copper electroplating composition on a working electrode, and a leveler, wherein the leveler is a copolymer of a reaction product of imidazole and butyldiglycidyl ether or a copolymer of a reaction product of imidazole and phenylimidazole;
d) contacting the substrate comprising the seed layer with the copper electroplating composition; and
e) anisotropically electroplating copper on the seed layer of the substrate.

The present invention is further directed to a method comprising:

a) providing a substrate comprising a seed layer;
b) coating the seed layer with photoresist;
c) imaging the photoresist to form a pattern on the substrate and selectively expose seed layer;
d) optionally applying an aqueous treatment solution comprising a sulfur containing accelerator to the exposed seed layer, wherein the aqueous treatment solution has a pH of 3 and below, or 9 and above;
e) providing a copper electroplating composition comprising a source of copper ions, an accelerator, an acid, a source of chloride, a suppressor which generates an α-peak curve in a cathodic wave of a voltammogram of the copper electroplating composition on a working electrode, and a leveler, wherein the leveler is a copolymer of a reaction product of imidazole and butyldiglycidyl ether or a copolymer of a reaction product of imidazole and phenylimidazole;
f) contacting the substrate comprising the seed layer with the copper electroplating composition; and
g) anisotropically electroplating anisotropic copper on the seed layer of the substrate.

The present invention is also directed to an article comprising a copper deposit that is plated to at least 2 μm above the height of the surrounding photoresist without resulting in feature broadening, and comprises incoherent boundaries orientated at 80-90° relative to the plane of a substrate and comprises concurrent twinned boundaries orientated at 40-50° relative to the plane of the substrate.

The methods of the present invention enable copper electroplating anisotropically of features having different shapes and sizes, which are maintained even when electroplated layer thickness is substantially higher than the thickness of the photoresist. The methods of the present invention enable formation of levelled features where the height can be maintained even if different aspect ratios and shapes are combined in a single layer or plating step. Additional advantages of the present invention are apparent to the person of ordinary skill in the art upon reading the disclosure and examples in the present specification.

### BRIEF DESCRIPTION OF THE DRAWINGS

FIG. 1 is a voltammogram of current (A) versus potential (V) showing α-peak and ΔV.

FIGS. 2A and 2B are illustrations of an isotropic copper feature and an anisotropic copper feature of the present invention, respectively.

FIG. 3 is an illustration of a surface activation method and anisotropically plating of a copper feature of the present invention.

FIGS. 4A and 4B are Fourier Transform maps showing the difference in orientation of non-coherent (A) and (111)-twinned (B) grain boundaries between copper line features plated with isotropic or anisotropic electroplating formulations.

### DETAILED DESCRIPTION OF THE INVENTION

As used throughout this specification, the following abbreviations shall have the following meanings, unless the context clearly indicates otherwise: A=amperes; A/dm²=amperes per square decimeter; ASD=A/dm²; V=voltage=electrical potential; ° C.=degrees Centigrade; g=gram; mg=milligram; L=liter; mL=milliliter; ppm=parts per million; ppb=parts per billion; M=moles/liter; mol=moles; nm=nanometers; μm=micron=micrometer; mm=millimeters; cm=centimeters; EBSD=electron backscatter spectroscopy; SEM=scanning electron micrograph; DI=deionized; Mw=weight average molecular weight; MES=2-mercapto-ethanesulfonic acid; NaOH=sodium hydroxide; PEG=polyethylene glycol; EO=ethylene oxide; PO=propylene oxide; PR=photoresist; H₂SO₄=sulfuric acid; Cu=copper; Ti=titanium; Pt=platinum; and PCB=printed circuit board.

As used throughout this specification, the term “bath” and “composition” are used interchangeably. “Plating” and “electroplating” are used interchangeably throughout this specification. The expression “(hkl)” is a Miller Indices and defines a specific crystal plane in a lattice. The term “Miller Indices: (hkl) mean the orientation of a surface of a crystal plane defined by considering how the plane (or any parallel plane) intersects the main crystallographic axis of a solid (i.e., the reference coordinates—x, y, and z axis as defined in a crystal, wherein x=h, y=k and z=1), wherein a set of numbers (hkl) quantify the intercepts and are used to identify the plane. The term “plane” means a two-dimensional surface (having length and width) where a straight line joining any two points in the plane would wholly lie. The term “crystal plane (111) orientation enrichment compound” means a chemical compound which increases exposure of metal grains, such as copper metal grains, having crystal plane (111) orientations at the area where metal is contacted with the chemical compound. The term “aspect ratio” means ratio of the height of a feature to the width of the surface the feature is plated on. The term “ppm” as used in the present specification is equivalent to mg/L. The term “aqueous” or “aqueous based” means the solvent is water. A “suppressor” refers to an organic additive that suppresses the plating rate of a metal during electroplating. The term “accelerator” means an organic compound that increases the plating rate of a metal, such compounds are often referred to as brighteners. The term “leveler” means an organic compound which enables a uniform metal deposit and can improve throwing power of an electroplating bath. The term “anisotropic” within the scope of the present invention means directionally or locally dependent—different properties in different directions or portions of a material such that the copper deposit grows predominantly in the vertical direction versus the horizontal direction. The term “isotropic” means within the scope of the present invention uniform non-directional or same properties in different directions or portions of a material where copper growth occurs substantially the same in the vertical and the horizontal direction. The term “morphology” means physical dimensions, such as height, length and width, and surface appearance of a feature. The terms “composition”, “solution” and “activator etch” are used interchangeably throughout the specification. The term “aperture” means opening and includes, but is not limited to, via, through-holes, trenches and through-silicon via. The articles “a” and “an” refer to the singular and the plural. All amounts in percent are by weight, unless otherwise noted. All numerical ranges are inclusive and combinable in any order, except where it is clear such numerical ranges are constrained to add up to 100%.

The present invention enables anisotropic copper electroplating of features to form anisotropic copper deposits with formation of incoherent copper grain boundaries (grain boundaries with misorientation between adjacent grains of 0° to 15°, preferably from greater than 0° but less than15°) that are substantially perpendicular or at 90° to the substrate and twinned copper grain boundaries (grain boundaries where atoms at the boundaries are shared by the lattices of both adjacent grains) that grow selectively at an oblique angle, such as 65°, to the substrate. In contrast, typical copper deposits that show isotropic electroplating growth display incoherent boundaries that are oriented at less than 80° relative to the substrate, or incoherent boundaries that show no selective orientation at all. Since the anisotropic performance arises from this selective orientation of incoherent boundaries within the electroplated copper deposit, the performance is less dependent on shape and spacing. In other words, since anisotropic plating is guided by the internal structure of the copper, once initiated, it is less dependent on continued surface interaction with the plating additives. Thus, differences in plating additive activity between features of different sizes, which are typically observed in isotropic plating baths, are not pronounced in anisotropic plating baths. For these reasons, the method of the present invention enables simultaneous anisotropic growth in features with different sizes (i.e. line widths from 1 to 100 μm, with a preferred size range of 1-10 μm), spacings (i.e. spacings from 1 to 100 μm, with preferred spacings range of 1-10 μm) and aspect ratios (i.e. aspect ratios from 0.1 to 5, with preferred spacings of 1-5).

The methods and compositions of the present invention can be used in anisotropic copper electroplating of many substrates such as, but not limited to, printed circuit boards and dielectric or semiconductor wafers with seed layers, such as copper seed layers, which enable electrical conductivity of the dielectric wafers. Such dielectric wafers include, but are not limited to, silicon wafers such as monocrystalline, polycrystalline and amorphous silicon, plastics such as Ajinomoto build-up film (ABF), acrylonitrile butadiene styrene (ABS), epoxides, polyimines, polyethylene terephthalate (PET), silica or alumina filled resins.

The methods and compositions of the present invention can electroplate anisotropic copper layers or anisotropic copper features, such as electrical circuitry, pillars, bond pads and line space features. The compositions and methods of the present invention can also be used to anisotropically electroplate copper in through-holes, via, trenches and TSV.

Copper features such as electrical circuitry, pillars, bond pads, vias and line features as well as other raised features of PCBs and dielectric wafers can be plated with or without using patterned masks, photo-tools or imaged photoresists to define the features. In general, imaging is done with photoresists to define features on a substrate. Both positive and negative conventional photoresist can be used to image the substrate. The copper electroplating methods and compositions of the present invention enable anisotropic copper deposits, such as raised features, to be plated to more than 12× the height of the imaged photoresist layers and still retain their morphology with minimal to no isotropic plating.

Regions or sections of the substrate which are to be electroplated with the copper electroplating compositions of the present invention include a seed layer, such as a copper seed layer, to make the selected regions or sections of the substrate conductive for copper electroplating. Preferably, the seed layer has predominantly (111) crystal plane orientation on the surface exposed to the plating bath. Conventional processes well known in the art for forming seed layers can be used. Such conventional methods include, but are not limited to, chemical vapor deposition, physical vapor deposition and electroless metal plating can be used. Preferably, the seed layer is of copper metal.

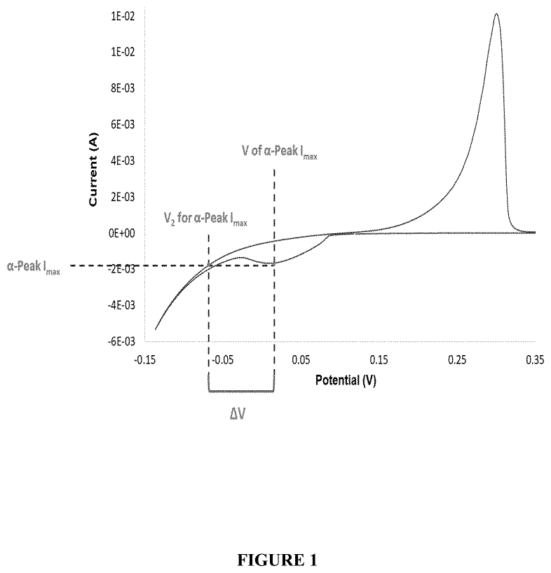

The copper electroplating compositions of the present invention show a characteristic α-peak curve in the cathode wave of a voltammogram of the plating bath collected on a working electrode, preferably, a Pt working electrode, as shown in FIG. 1. The more pronounced the α-peak of the α-peak curve, the more anisotropic is the copper deposit. The α-peak or α-Peak Iₘₐₓ as shown in FIG. 1 is at the apex of the α-peak curve. The tendency to yield anisotropic growth is quantified by calculating ΔV, as shown in FIG. 1. ΔV=V₂ for α-Peak Iₘₐₓ−V of α-Peak Iₘₐₓ where the V₂ for α-Peak Iₘₐₓ is the voltage or potential at the apex of the α-peak curve as shown by the second vertical dotted line of FIG. 1, and V of α-Peak Iₘₐₓ is the voltage where a horizontal dotted line from the apex of the α-peak curve intersects the cathodic wave also as illustrated in FIG. 1 by a first vertical dotted line.

The α-peak curve in the cathodic wave of a voltammogram as described above is preferably used to select suppressors for copper electroplating compositions to enable the plating of anisotropic copper deposits. Various compounds known for their suppressor activity can be tested to determine their ability to enable anisotropic copper deposits. If a copper electroplating composition containing a suppressor provides a voltammogram curve with an α-peak curve in the cathodic wave, the suppressor can be used to electroplate anisotropic copper deposits. The greater the ΔV, the more anisotropic the copper deposit plated from the copper electroplating composition with the specific suppressor.

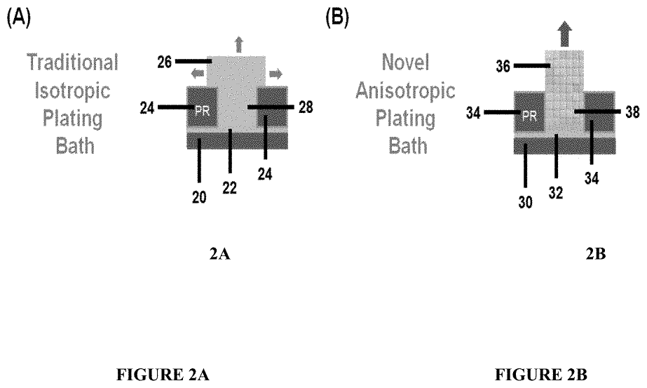

FIGS. 2A and 2B illustrate and compare an isotropic deposited copper line of a conventional copper electroplating bath versus a copper line electroplated from an anisotropic copper electroplating bath of the present invention. FIG. 2A illustrates a dielectric substrate 20, such as a silicon wafer, coated with a copper seed layer 22. Imaged photoresist 24 coats the seed layer 22. An isotropic copper line 26 is shown deposited within a recession 28 in the imaged photoresist. The three arrows indicate the growth of the copper pillar and its isotropic character where sections of the line overlap the imaged photoresist 24 indicating copper deposition in the horizontal direction. The vertical arrow indicates copper growth in the vertical direction at the same time as horizontal growth. In contrast, FIG. 2B illustrates a dielectric substrate 30, such as a silicon wafer, coated with a copper seed layer 32. Imaged photoresist 34 coats the seed layer 32. An anisotropic copper pillar 36 is shown deposited within a recession 38 in the imaged photoresist. The vertical arrow indicates the anisotropic character of copper pillar 36 where copper deposition occurs only in the horizontal direction once the copper growth exceeds the height of the imaged photoresist. There is no horizontal copper growth over the imaged photoresist 34.

The anisotropic copper electroplating compositions of the present invention are aqueous based and include a source of copper ions. Copper ion sources are copper salts and include but are not limited to, copper sulfate; copper halides such as copper chloride; copper acetate; copper nitrate; copper fluoroborate; copper alkylsulfonates; copper arylsulfonates; copper sulfamate; and copper gluconate. Exemplary copper alkylsulfonates include copper (C₁-C₆)alkylsulfonate and copper (C₁-C₃)alkylsulfonate. Preferably, copper alkylsulfonates are copper methanesulfonate, copper ethanesulfonate and copper propanesulfonate. Exemplary copper arylsulfonates include, but are not limited to copper phenyl sulfonate, copper phenol sulfonate and copper p-toluene sulfonate. Mixtures of copper ion sources can be used.

The copper salts can be used in the aqueous anisotropic copper electroplating baths in amounts that provide sufficient copper ion concentrations for electroplating copper on a substrate. Preferably, the copper salt is present in an amount sufficient to provide an amount of copper ions of 10 g/L to 180 g/L of plating solution, more preferably, from 20 g/L to 100 g/L.

Acids can be included in the anisotropic copper electroplating baths. Acids include, but are not limited to, sulfuric acid, fluoroboric acid, alkanesulfonic acids such as methanesulfonic acid, ethanesulfonic acid, propanesulfonic acid and trifluoromethane sulfonic acid, arylsulfonic acids such as phenyl sulfonic acid, phenol sulfonic acid and toluene sulfonic acid, sulfamic acid, hydrochloric acid, and phosphoric acid. Mixtures of acids can be used in the copper electroplating baths. Preferably, acids include sulfuric acid, methanesulfonic acid, ethanesulfonic acid, propanesulfonic acid, and mixtures thereof.

Acids are preferably present in amounts of 1 g/L to 300 g/L, more preferably, from 5 g/L to 250 g/L, further preferably, from 10 to 150 g/L. Acids are generally commercially available from a variety of sources and can be used without further purification.

A source of halide ions can be included in the anisotropic copper electroplating baths. Halide ions are preferably chloride ions. A preferred source of chloride ions is hydrogen chloride. Chloride ion concentrations are in amounts of 1 ppm to 100 ppm, more preferably, from 10 to 100 ppm, further preferably, from 20 to 75 ppm.

Accelerators include, but are not limited to, 3-mercapto-propylsulfonic acid and its sodium salt, 2-mercapto-ethanesulfonic acid and its sodium salt, and bissulfopropyl disulfide and its sodium salt, 3-(benzthiazoyl-2-thio)-propylsulfonic acid sodium salt, 3-mercaptopropane-1-sulfonic acid sodium salt, ethylenedithiodipropylsulfonic acid sodium salt, bis-(p-sulfophenyl)-disulfide disodium salt, bis-(ω-sulfobutyl)-disulfide disodium salt, bis-(ω-sulfohydroxypropyl)-disulfide disodium salt, bis-(ω-sulfopropyl)-disulfide disodium salt, bis-(ω-sulfopropyl)-sulfide disodium salt, methyl-(ω-sulfopropyl)-disulfide sodium salt, methyl-(ω-sulfopropyl)-trisulfide disodium salt, O-ethyl-dithiocarbonic acid-S-(ω-sulfopropyl)-ester, potassium salt thioglycoli acid, thiophosphoric acid-O-ethyl-bis-(ω-sulfpropyl)-ester disodium salt, thiophosphoric, acid-tris(ω-sulfopropyl)-ester trisodium salt, N,N-dimethyldithiocarbamic acid (3-sulfopropyl) ester, sodium salt, (O-ethyldithiocarbonato)-S-(3-sulfopropyl)-ester, potassium salt, 3-[(amino-iminomethyl)-thio]-1-propanesulfonic acid and 3-(2-benzthiazolylthio)-1-propanesulfonic acid, sodium salt. Preferably the accelerator is bissulfopropyl disulfide or its sodium salt. Preferably, accelerators are included in copper electroplating baths in amounts of 1 ppb to 500 ppm, more preferably from 50 ppb to 50 ppm, most preferably, from 5 ppm to 40 ppm.

Preferably, suppressors include, but are not limited to polyethylene glycol polymers having a weight average molecular weight of 1000-6000 g/mol, random and block ethylene oxide-propylene oxide (“EO/PO”) copolymers having a weight average molecular weight of 1000-5000 g/mol.

More preferably, the suppressors are diamine core-EO/PO surfactants, preferably, having the general formula:

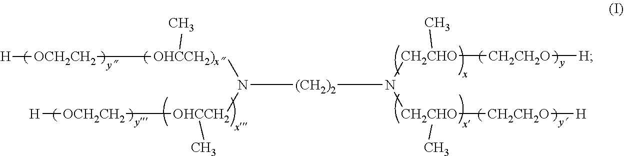

with weight average molecular weights of 1000-10,000 g/mol and commercially available from BASF, Mount Olive, N.J. as TECTRONIC® surfactants; and

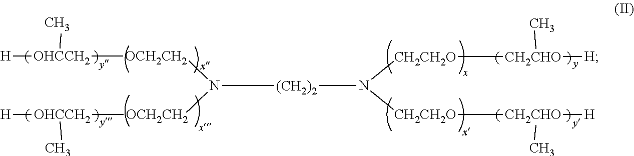

with weight average molecular weight of 1000-10,000 g/mol and commercially available from BASF as TECTRONIC® R surfactants, wherein the variables x, x′, x″, x″′, y, y′, y″ and y″′ are integers equal to or greater than 1 such that the weight average molecular weights of the copolymers range from 1000-10,000 g/mol.

Most preferred are the diamine-core polymers terminated with 1 to 4 sulfonic acid groups. Most preferred examples are the diamine-core polymers having a general formula:

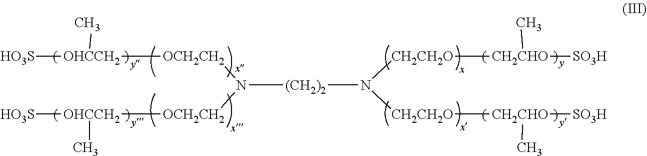

with weight average molecular weight ranges from 1000-10,000 g/mol and variables x, x″, x″, x″′, y, y′, y″ and y″′ are independently integers greater than or equal to 1 to provide the molecular weight range of 1000-10,000 g/mol.

Suppressors are preferably included in the copper electroplating baths in amounts of 0.5 g/L to 20 g/L, more preferably, from 1 g/L to 10 g/L, further preferably, from 1 g/L to 5 g/L.

Preferably, levelers include copolymers of reaction products of imidazole and butyldiglycidylether or imidazole and phenylimidazole. Preferably, such leveling agents have a weight average molecular weight of 1000 g/mol to 50,000 g/mol. Such levelers can be prepared by methods disclosed in the literature or by methods known to those of ordinary skill in the art.

The levelers are preferably included in the copper electroplating baths in amounts of 0.01 ppm to 100 ppm, more preferably, from 0.01 ppm to 10 ppm, further preferably, from 0.01 ppm to 1 ppm.

Optionally, a pH adjusting agent can be included in the compositions to maintain a desired pH. One or more inorganic and organic acids can be included to adjust the pH of the compositions. Inorganic acids include, but are not limited to, sulfuric acid, hydrochloric acid, nitric acid and phosphoric acid. Organic acids include, but are not limited to, citric acid, acetic acid, alkane sulfonic acids, such a methane sulfonic acid. Bases which can be included in the compositions include, but are not limited to, sodium hydroxide, potassium hydroxide, ammonium hydroxide and mixtures thereof.

The pH of the copper electroplating compositions ranges from 0-14, preferably, from 0-6, more preferably from 0-4.

To provide an electrically conductive substrate for copper electroplating, the substrates of the present invention include a selectively deposited seed layer, such as copper seed layer, to make the substrate conductive. The selectively deposited seed layer is then copper plated to provide an anisotropic copper deposit on the selective seed layer. Once the seed layer is copper coated, continued copper plating results in vertical copper growth with minimal to no horizontal copper deposition. Alternatively, the entire surface of the substrate includes a seed layer coating. A photoresist material is applied over the seed layer and the photoresist is imaged using conventional processes known in the art to form a pattern or features on the substrate. The photoresist can be one of many conventional photoresists known to those of ordinary skill in the art. The photoresist can be a negative or positive acting photoresist. Due to the anisotropic character of the copper electroplating compositions of the present invention, the thickness of any photoresist applied to a surface of the substrate can be thinner than the thickness of the electroplated copper layer.

A substrate can be electroplated with copper by contacting the substrate with the plating composition. The substrate functions as the cathode. The anode can be a soluble or insoluble anode. Sufficient current density is applied and plating is performed for a time to deposit copper having a desired thickness and morphology on the substrate. Current densities can range from 0.5 ASD to 30 ASD, preferably from, 0.5 ASD to 20 ASD, more preferably from 1 ASD to 10 ASD, further preferably from 1 ASD to 5 ASD.

The temperature of the copper electroplating baths during electroplating range, preferably, from room temperature to 65° C., more preferably, from room temperature to 35° C., further preferably, from room temperature to 30° C.

The copper electroplating compositions and methods of the present invention can copper electroplate anisotropically fine lines of 1-100 μm, or such as from 1-50 μm, or such as from 1-5 μm in width and up to 40 μm in height.

Optionally, but preferably, prior to copper electroplating, the seed layer can be treated with an aqueous treatment solution containing one or more sulfur containing accelerator compounds. The pre-copper electroplating treatment solution further enables anisotropic copper electroplating. The treatment solution can be applied to the selectively deposited seed layer, followed by anisotropic copper electroplating. The aqueous treatment solution has a pH of below 3, such as from 0 to less than 3, or above 9, such as greater than 9 to 14.

Alternatively, the substrate containing seed layer coating the entire surface of the substrate can be coated with photoresist, imaged to form a pattern and the treatment solution can be applied such that the treatment solution contacts the exposed seed at the bottom of the imaged sections of the photoresist. The remaining photoresist can then be stripped from the substrate with a conventional photoresist stripper. The treated seed layer is then copper plated with a copper plating composition of the present invention. Copper electroplating anisotropically occurs on the seed layer treated with the treatment solution, not untreated seed layer. Optionally, copper electroplating can be done after application of the treatment solution but prior to stripping the imaged photoresist from the substrate. After copper electroplating, the photoresist can be stripped from the substrate.

Sulfur containing accelerators include many of the accelerators which are included in the copper electroplating compositions of the present invention. Accelerators include, but are not limited to, 3-mercapto-propylsulfonic acid and its sodium salt, 2-mercapto-ethanesulfonic acid and its sodium salt, and bissulfopropyl disulfide and its sodium salt, 3-(benzthiazoyl-2-thio)-propylsulfonic acid sodium salt, 3-mercaptopropane-1-sulfonic acid sodium salt, ethylenedithiodipropylsulfonic acid sodium salt, bis-(p-sulfophenyl)-disulfide disodium salt, bis-(ω-sulfobutyl)-disulfide disodium salt, bis-(ω-sulfohydroxypropyl)-disulfide disodium salt, bis-(ω-sulfopropyl)-disulfide disodium salt, bis-(ω-sulfopropyl)-sulfide disodium salt, methyl-(ω-sulfopropyl)-disulfide sodium salt, methyl-(ω-sulfopropyl)-trisulfide disodium salt, O-ethyl-dithiocarbonic acid-S-(ω-sulfopropyl)-ester, potassium salt thioglycoli acid, thiophosphoric acid-O-ethyl-bis-(ω-sulfpropyl)-ester disodium salt, thiophosphoric, acid-tris(ω-sulfopropyl)-ester trisodium salt, N,N-dimethyldithiocarbamic acid (3-sulfopropyl) ester, sodium salt, (O-ethyldithiocarbonato)-S-(3-sulfopropyl)-ester, potassium salt, 3-[(amino-iminomethyl)-thio]-1-propanesulfonic acid and 3-(2-benzthiazolylthio)-1-propanesulfonic acid, sodium salt. Preferably the accelerator is 2-mercapto-ethanesulfonic acid and its sodium salt. Preferably, accelerators are included in copper electroplating baths in amounts of 1 ppb to 500 ppm, more preferably from 50 ppb to 50 ppm, most preferably, from 5 ppm to 40 ppm.

Optionally, one or more surfactants can be included in the treatment solution of the present invention. Such surfactants include non-ionic surfactants, cationic surfactants, anionic surfactants and amphoteric surfactants. For example, non-ionic surfactants can include, polyesters, polyethylene oxides, polypropylene oxides, alcohols, ethoxylates, silicon compounds, polyethers, glycosides and their derivatives; and anionic surfactants can include anionic carboxylates or organic sulfates such as sodium lauryl either sulfate (SLES).

Surfactants can be included in conventional amounts. Preferably, when surfactants are included in the treatment solutions of the present invention they are included in amounts of 0.1 g/L to 10 g/L.

The treatment solutions of the present invention can be applied at temperatures from room temperature to 60° C., preferably, from room temperature to 30° C., more preferably the compositions are applied to copper at room temperature.

The treatment solution of the present invention can be applied by immersing a substrate with a seed layer in the solution, by spraying the solution on the substrate, spin-coating, or other conventional method for applying solutions to a substrate. The treatment solutions of the present invention can also be selectively applied to copper. Selective application can be done by any conventional method for selectively applying solutions to a substrate. Such selective applications include, but are not limited to ink jet application, writing pens, eye droppers, polymer stamps having patterned surfaces, masks such as by imaged photoresist or screen printing.

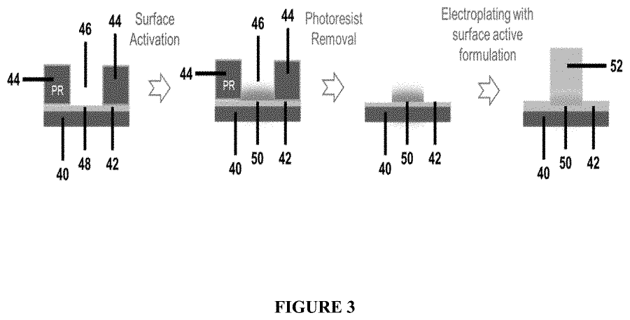

FIG. 3 illustrates the method of the present invention with the application of the treatment solution and an anisotropic copper line deposited according the method of the present invention. A substrate 40 is coated with a copper seed layer 42 and the copper seed layer is coated with imaged photoresist 44 having a height of 3 μm with opening 46. The section of the seed layer exposed 48 at the bottom of the opening 46 is treated with a treatment solution containing MES to provide treated seed layer 50. The photoresist is then stripped leaving the treated seed layer 50. The treated seed layer is then plated with an anisotropic copper electroplating bath of the present invention where copper line growth occurs vertically only on the seed layer treated with the treatment solution and then the remaining copper growth is isotropic to form a copper line 52.

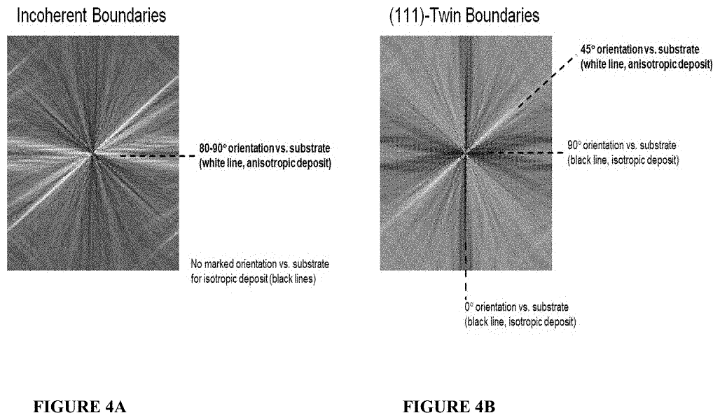

FIGS. 4A and 4B illustrate the structure of anisotropically-plated copper through analysis of grain boundary analysis of cross sections of line features electroplated with either anisotropic or isotropic copper. FIG. 4A is a difference Fourier Transform map of the anisotropically grown line feature (white lines) minus an isotropically grown line feature (black lines), showing the orientation of non-coherent grain boundaries relative to the substrate. A white horizontal line indicates that these boundaries of the anisotropically grown line are preferentially oriented at 90° relative to the substrate, which suggests that they curtail lateral growth of the plated copper and thus ensure anisotropic plating growth. FIG. 4B is a similar difference Fourier Transform map of the anisotropically grown line feature minus an isotropically grown line feature, showing the orientation of (111)-twinned grain boundaries relative to the substrate. Two white diagonal lines indicate that the twinned boundaries of the anisotropically grown line are oriented at ˜45° relative to the substrate, which suggests that grain growth within the confines of incoherent boundaries occurs via deposition over (111)-twinned planes.

An article of the present invention includes a copper deposit that is plated to at least 2 μm above the height of the surrounding photoresist without resulting in feature broadening, and which includes incoherent boundaries orientated at 80-90° relative to the plane of a substrate and includes concurrent twinned boundaries orientated at 40-50° relative to the plane of the substrate.

The following examples are included to further illustrate the invention but are not intended to limit its scope.

### Examples 1-2

### Plating Height Levelling on 3-mercapto-propylsulfonic Acid Sodium Salt Activated 1-100 μm Fine-line Pattern with Highly Anisotropic Bath 3, vs. No Activation with Isotropic Bath 1

The following two copper electroplating baths were prepared:

### Plating Bath 1 (Isotropic Bath):

50 g/L Cu(II) ion
100 g/L H2SO₄
50 ppm Chloride ion
5 ppm Bis-Sodium-Sulfopropyl-Disulfide
2 g/L EO-PO random copolymer with average MW 1,100 and hydroxyl end groups 5 ppm reaction product of epichlorohydrin and imidazole

### Plating Bath 2 (Anisotropic Bath):

50 g/L Cu(II) ion
100 g/L H2SO4
50 ppm Chloride ion
40 ppm Bis-Sodium-Sulfopropyl-Disulfide
2 g/L EO-PO random copolymer with average MW 1,100 and hydroxyl end groups
1 ppm reaction product of butyldiglycidylether, imidazole and phenylimidazole

### Plating Bath 3 (Anisotropic Bath):

50 g/L Cu(II) ion
100 g/L H2SO₄
50 ppm Chloride ion
20 ppm Bis-Sodium-Sulfopropyl-Disulfide
2 g/L Diamine core-EO/PO block co-polymer with and average MW of 7,000
0.1 ppm reaction product of butyldiglycidylether, imidazole and phenylimidazole

A silicon wafer coated with a 20 nm Ti adhesion layer and a 200 nm conductive Cu seed was laminated with a positive-tone Shipley BPR™ 100 PR layer with a thickness of 3 μm. A fine line pattern was built on the PR layer to contain a series of trenches ranging from 6 to 100 μm in width. These trenches were then plated to a target height of 4.5 μm using either Plating Bath 1 or Plating Bath 3. The sample plated with Plating Bath 1 was wetted with DI water prior to plating. The sample plated with Plating Bath 3 was first immersed in a pH 0.7 solution of 4 g/L MES in water and then rinsed with DI water prior to plating. In both cases, electroplating was carried out at 2 ASD with a cathode rotation rate of 50 rpm. Following plating, the PR was removed using Shipley BPR™ Stripper at 80° C. for 10 minutes to yield a pattern of fine lines. The sample was then exposed to an etch solution containing 84 mL/L of 85% phosphoric acid and 8 mL/L of 45.5% hydrogen peroxide solution to remove the remaining conductive seed that had been protected by the PR. The height of the isolated Cu fine-lines was determined using a laser profilometer from Keyence Corporation. The results, summarized in Table 1, showed that both plating baths produced highly levelled deposits where the plating height was uniform regardless of changes in feature size. These results showed that anisotropic plating was possible while still achieving a highly levelled deposit over a wide range of line sizes, as typically afforded by Plating Bath 1.

TABLE 1

| | Anisotropic | Isotropic |
|---|---|---|
| | Bath | Bath |
| Lines | Plating | Plating |
| Width | Height | Height |
| (μm) | (μm) | (μm) |
| 6 | 4.616 | 5.631 |
| 7 | 4.652 | 5.541 |
| 8 | 4.828 | 5.709 |
| 9 | 5.228 | 5.641 |
| 10 | 5.241 | 5.710 |
| 15 | 5.426 | 5.646 |
| 20 | 5.383 | 5.625 |
| 25 | 5.094 | 5.631 |
| 30 | 4.946 | 5.594 |
| 35 | 4.897 | 5.640 |
| 40 | 4.849 | 5.639 |
| 45 | 4.793 | 5.594 |
| 50 | 4.885 | 5.622 |
| 60 | 4.703 | 5.645 |
| 70 | 4.650 | 5.676 |
| 80 | 4.635 | 5.488 |
| 90 | 4.807 | 5.497 |
| 100 | 4.842 | 5.629 |

### Examples 3-6

### Line Broadening on MES Activated 1-100 μm Fine-line Pattern with Highly Surface Reactive Bath 2, vs. No Activation with Non-surface Reactive Bath 1

A silicon wafer coated with a 20 nm Ti adhesion layer and a 200 nm conductive Cu seed was laminated with a PR layer with a thickness of 3 μm. A fine line pattern was built on the PR layer to contain a series of trenches ranging from 1 to 100 μm in width. These trenches were then plated to a target height of 4.5 μm using either Plating Bath 1 or Plating Bath 3. In each case, the samples were either wetted with DI water prior to plating, or they were first immersed in a pH 0.7 solution of 4 g/L MES in water and then rinsed with DI water prior to plating. In all cases, electroplating was carried out at 2 ASD with a cathode rotation rate of 50 rpm. Following plating, the PR was removed in a PR stripper bath to yield a pattern of fine lines. The sample was then exposed to a seed etch solution to remove the remaining conductive seed that had been protected by the PR. The width of the isolated Cu fine-lines was determined using a laser profilometer. The results, summarized in Table 2, showed that Plating Bath 3 prevented significant line broadening even though the target plating height was significantly above the height of the PR layer. On the other hand, the samples prepared with Plating Bath 1 showed significant line broadening regardless of any pretreatment. In areas of the sample where the line pitch was small, this broadening resulted in fusion of adjacent Cu lines.

TABLE 2

| | Anisotropic | Anisotropic | Isotropic | Isotropic |
|---|---|---|---|---|
| | Bath Plating | Bath Plating | Bath Plating | Bath Plating |
| | Width - | Width - DI | Width - | Width - DI |
| Lines | with | Water only | with | Water only |
| Width | Pretreatment | Pretreatment | Pretreatment | Pretreatment |
| (μm) | (μm) | (μm) | (μm) | (μm) |
| 6 | −0.435 | 0.459 | 1.378 | 1.503 |
| 7 | −0.556 | −1.514 | 1.022 | 1.337 |
| 8 | −0.370 | −0.104 | 1.426 | 2.025 |
| 9 | −0.298 | −0.281 | 1.052 | 1.670 |
| 10 | −0.179 | −0.172 | 1.192 | 1.579 |
| 15 | −0.533 | −0.142 | 1.264 | 1.369 |
| 20 | 0.153 | −0.139 | 1.491 | 1.659 |
| 25 | 0.030 | −0.047 | 0.794 | 1.421 |
| 30 | 0.103 | −0.078 | 1.023 | 1.515 |
| 35 | −0.147 | −0.284 | 1.757 | 1.711 |
| 40 | −0.889 | −0.599 | 1.468 | 1.749 |
| 45 | −0.286 | −0.270 | 1.256 | 1.559 |
| 50 | −0.051 | 0.045 | 0.506 | 1.854 |
| 60 | 0.452 | 0.213 | 1.493 | 1.885 |
| 70 | −0.177 | 0.033 | 0.849 | 1.527 |
| 80 | 0.043 | 0.807 | 1.129 | 1.642 |
| 90 | 0.021 | 0.364 | 1.438 | 1.785 |
| 100 | −0.011 | 0.478 | 2.577 | 2.509 |

### Examples 7-10

### Line Broadening on MES Activated 1-100 μm Fine-line Pattern with Highly Surface Reactive Bath 3, vs. No Activation with Non-surface Reactive Bath 1

A silicon wafer coated with a 20 nm Ti adhesion layer and a 200 nm conductive Cu seed was laminated with a PR layer with a thickness of 3 μm. A fine line pattern was built on the PR layer to contain a series of 100 μ-wide trenches. The substrate was then plated to a target height of 36 μm using either Plating Bath 1 or Plating Bath 3. The sample plated with Plating Bath 1 was wetted with DI water prior to plating. The sample plated with Plating Bath 3 was first immersed in a pH 0.7 solution of 4 g/L MES in water and then rinsed with DI water prior to plating. In both cases, electroplating was carried out at 2 ASD with a cathode rotation rate of 50 rpm. Following plating, the PR was removed in a PR stripper bath to yield a pattern of fine lines. The samples were then imaged via SEM. Table 3 show that the sample plated with Plating Bath 1 results in complete line fusion, while the sample plated with Plating Bath 3 does not exhibit any significant line broadening and the plated deposit has grown anisotropically following the shape of the thinner PR pattern.

A fine line pattern was then built on the 3 μm PR layer of a similar substrate to contain a series of trenches with widths ranging from 1 to 5 μm. This substrate was then similarly plated using the same process flow as above, with the only difference being a lower plating target height of 6 μm. Table 3 shows that the sample plated with Plating Bath 1 resulted in complete line fusion, while the sample plated with Plating Bath 3 did not exhibit any significant line broadening and the plated deposit grew anisotropically following the shape of the thinner PR pattern.

TABLE 3

| Lines | Anisotropic | Isotropic |
|---|---|---|
| Width | Bath | Bath |
| (μm) | Plating | Plating |
| 1 | No Fusion | Complete |
| | | Fusion |
| 2 | No Fusion | Complete |
| | | Fusion |
| 3 | No Fusion | Complete |
| | | Fusion |
| 4 | No Fusion | Complete |
| | | Fusion |
| 5 | No Fusion | Complete |
| | | Fusion |
| 100 | No Fusion | Complete |
| | | Fusion |

### Example 11-18

### Impact of Surface Activation vs. No Surface Activation with Different Plating Baths on 100 μm-wide Lines

A silicon wafer coated with a 20 nm Ti adhesion layer and a 200 nm conductive Cu seed was laminated with a PR layer with a thickness of 3 μm. A fine line pattern was built on the PR layer to contain a series of 100 μ-wide trenches. The substrate was then plated to a target height of 6 μm using 4 different plating bath formulations. In each case, the samples were either wetted with DI water prior to plating or they were first immersed in a pH 0.7 solution of 4 g/L MES in water and then rinsed with DI water prior to plating. In all cases, electroplating was carried out at 10 ASD with a cathode rotation rate of 50 rpm. Following plating, the PR was removed in a PR stripper bath to yield a pattern of fine lines. The samples were then resin molded and cross-sectioned using an argon plasma. This was followed by SEM imaging to observe the impact of the plating formulation on the line shape and uniformity. The summary of the results is below.

Example 11 and 12 were plated with Plating Bath 3. Example 11 was pretreated with the MES solution, while Example 12 was only prewetted with DI water. Example 11 showed that a homogeneous line shape and anisotropic growth along the edges of the line. Example 12 results in a severely non-homogeneous line shape and anisotropic growth along the edges of the line.

Example 13 and 14 were plated with Plating Bath 2. Example 13 was pretreated with the MES solution, while Example 14 was only prewetted with DI water. Example 13 showed a homogeneous line shape and mildly anisotropic growth along the edges of the line. Herein, a mildly anisotropic bath is a formulation that produces less line broadening than Plating Bath 1, and which leads to plated deposit growth direction of 75-89° relative to the substrate when plating above the height of the PR. Example 14 showed a non-homogeneous line shape and mildly anisotropic growth along the edges of the line.

Examples 15 and 16 were plated with Plating Bath 4, which contained:
50 g/L Cu(II) ion
100 g/L H₂SO₄
50 ppm Chloride ion
40 ppm Bis-Sodium-Sulfopropyl-Disulfide
2 g/L EO-PO block copolymer with average MW 1,100 and hydroxyl end groups
1 ppm reaction product of butyldiglycidylether, imidazole and phenylimidazole

Example 15 was pretreated with the MES solution, while Example 16 was only prewetted with DI water. Example 15 showed a homogeneous line shape and mildly isotropic growth along the edges of the line. A mildly isotropic bath was a formulation that produced less line broadening than Plating Bath 1 and which led to plated deposit growth direction of 40-74° relative to the substrate when plating above the height of the PR. Example 14 showed a non-homogeneous line shape and isotropic growth along the edges of the line.

Examples 17 and 18 were plated with Plating Bath 1. Example 17 was pretreated with the MES solution, while Example 18 was only prewetted with DI water. Example 17 showed a homogeneous line shape and strongly isotropic growth along the edges of the line. Example 18 showed a homogeneous line shape and strongly isotropic growth along the edges of the line.

Examples 11-18 were cross-sectioned and then analyzed via EBSD to determine differences in microstructure that are brought along with increased anisotropic plating behavior. Towards this end, the length of all boundaries in each cross-section was analyzed and divided by the corresponding cross-section surface area to obtain a boundary density. It was thus found that the more pronounced the anisotropic growth behavior of the plating bath formulation, the more the twinned-boundary density will increase upon seed activation with the MES solution. This trend is shown in Table 4. In addition, it is observed that all samples contain Cu deposits with small grains immediately after plating, but Cu grain size increases at different rates at room temperature depending on the plating formulation. By the time the samples are cross-sectioned and analyzed, the grain size of the highly isotropic growth Examples 17-18 is larger than the grain sizes of highly anisotropic Examples 11-12. Grain growth may continue until a stable grain boundary is formed, such as a twinned boundary. This suggests that the relatively high twinned density in Examples 17-18 may come about as a result of the subsequent grain growth rather than an inherent propensity of Plating Bath 1 to produce a high twinned boundary density. Thus, the data suggests that anisotropic growth is accompanied by a higher propensity to form twinned boundaries during plating.

TABLE 4

| | | | Incoherent | Twinned |
|---|---|---|---|---|
| | | | Boundary | Boundary |
| | | Twinned | Orientation | Orientation |
| | Plating | Boundary | Relative to | Relative to |
| | Growth | Density | Substrate | Substrate |
| Example | Type | (μm/μm²) | (°) | (°) |
| 11 | Strongly | 1.392405 | 90 | 45 |
| | Anisotropic | | | |
| 12 | Anisotropic | 0.999652 | 85 | 49 |
| 13 | Mildly | 1.07675 | 78 | 57 |
| | Anisotropic | | | |
| 14 | Mildly | 0.965766 | 81 | No clear |
| | Anisotropic | | | preferred |
| | | | | orientation |
| 15 | Mildly | 0.857398 | 73 | No clear |
| | Isotropic | | | preferred |
| | | | | orientation |
| 16 | Isotropic | 0.843953 | 59 | No clear |
| | | | | preferred |
| | | | | orientation |
| 17 | Strongly | 1.103944 | 65 | 90 & 0 |
| | Isotropic | | | |
| 18 | Strongly | 1.086809 | 60 | 90 |
| | Isotropic | | | |

The EBSD data was further processed via Fourier analysis to investigate whether anisotropic growth was accompanied by a change in boundary orientation relative to the substrate. The Fourier transform maps for Example 11 were subtracted by the map for Example 18 for either all incoherent boundaries for the (111)-twinned boundaries. The resulting difference maps are shown in FIGS. 4A and 4B. Horizontal lines indicate boundary alignment perpendicular to the plating substrate, whereas vertical lines indicate parallel boundary alignment. White lines correspond to preferential alignment in anisotropic growth Example 11 and black lines correspond to preferential alignment in isotropic growth Example 18. The data showed that anisotropic growth was accompanied by preferential alignment of incoherent boundaries perpendicular to the substrate, while anisotropic growth was correlated with a less-defined preference. In the case of (111)-twinned boundaries, the isotropic growth sample showed perpendicular and parallel orientation, whereas the anisotropic sample showed a moderate preference for orienting (111)-twinned boundaries at ˜45° relative to the substrate.

Taken together, the twinned boundary density and Fourier analysis data suggest that anisotropic growth results from a preference to undergo deposition or nucleate new grains over twinned boundaries. The lower preference for growth over incoherent boundaries results in a tendency for these boundaries to pin the deposit along the thickness of the deposit, preventing it from extending outwards, and thus resulting in anisotropic growth. On the other hand, the ability of all boundaries to extend in lateral directions along the thickness of the deposit in the isotropic sample provides a path for Cu to grow with no preferential direction.

### Examples 19-25

### Designing Plating Baths that are Responsive to Surface-Activation and Increase Plating Growth Angle

The growth angle of the plated deposit can be tuned by changing the plating composition. One key variable in the formulation is the choice of suppressor additive. Thus, to investigate the impact of suppressor on line broadening, different suppressors were incorporated into baths containing:
50 g/L Cu(II) ion
100 g/L H₂SO₄
50 ppm Chloride ion
40 ppm Bi s-Sodium-Sulfopropyl-Di sulfide
2 g/L suppressor additive
Example 19: PEG MW 1,000
Example 20: Block EO-PO MW 1,100
Example 21: Block EO-PO MW 1,950
Example 22: Random EO/PO MW 1,100
Example 23: Reverse Tetronic MW 3,750
Example 24: Reverse Tetronic MW 5,300
Example 25: Reverse Tetronic with Sulfonated End Groups, MW 4,800

0.1 ppm reaction product of butyldiglycidylether, imidazole and phenylimidazole The formulations were analyzed via cyclic voltammetry using a Pt rotating working electrode (10 rpm, 10 mV/s scan rate, 25° C.), a common analysis tool for Cu electroplating baths as shown in FIG. 1. It was observed that the more pronounced the anisotropic growth produced by a given formulation, the more pronounced the α-peak feature in the cathodic wave of the CVS would become. Thus, the tendency to yield anisotropic growth was quantified by calculating ΔV, as shown in FIG. 1. The plating bath from Example 19 resulted in a ΔV of 0.003 V; Example 20 resulted in a ΔV of 0.049 V; Example 21 resulted in a ΔV of 0.076 V; Example 22 resulted in a ΔV of 0.093 V; Example 23 resulted in a ΔV of 0.094 V; Example 24 resulted in a ΔV of 0.095 V; Example 25 resulted in a ΔV of 0.101 V.

### Examples 26-35

### Control of Feature Broadening in 1-60 μm Wide Feature Pattern with Different Suppressor Additives

A silicon wafer coated with a 20 nm Ti adhesion layer and a 200 nm conductive Cu seed was laminated with a PR layer with a thickness of 3 μm. A fine line pattern was built on the PR layer to contain a series of trenches ranging from 1 to 60 μm in width. These trenches were then plated to a target height of 6 μm using 10 different plating bath formulations that differed in the identity of the suppressor additive:
50 g/L Cu(II) ion
100 g/L H₂SO₄
50 ppm Chloride ion
40 ppm Bis-Sodium-Sulfopropyl-Disulfide
0.1 ppm reaction product of butyldiglycidylether, imidazole and phenylimidazole
2 g/L suppressor additive

Example 26: Block EO-PO MW 1,100
Example 27: Block EO-PO MW 1,950
Example 28: Block EO-PO MW 4,950
Example 29: Random EO/PO MW 1,100
Example 30: PEG MW 1,000
Example 31: PEG MW 6,000
Example 32: Reverse Tetronic MW 3,750
Example 33: Reverse Tetronic MW 5,300
Example 34: Reverse Tetronic MW 7,250
Example 35: Reverse Tetronic with sulfonated end groups, MW 4,800
   Each sample was rinsed with DI water prior to plating. In all cases, electroplating was carried out at 2 ASD with a cathode rotation rate of 50 rpm. Following plating, the PR was removed in a PR stripper bath to yield a pattern of fine lines. The samples were then exposed to Cu and Ti etch solutions to remove the remaining conductive seed that had been protected by the PR. Finally, the width of the plated lines was determined via laser profilometry.

The results are tabulated in Table 6. The results showed that reversed Tetronic-type suppressors are most effective at minimizing line broadening; while sulfonation of the Tetronic end groups leads to the most pronounced anisotropic plating and almost no line broadening when plating above the PR.

TABLE 6
Effect of Suppressor on Fine-Line Broadening (6 μm Height, 3 μm PR)

| PR Trench | | | | | | | | | | |
|---|---|---|---|---|---|---|---|---|---|---|
| Width | Plating Line Broadening (μm) | | | | | | | | | |
| (μm) | Ex. 26 | Ex. 27 | Ex. 28 | Ex. 29 | Ex. 30 | Ex. 31 | Ex. 31 | Ex. 33 | Ex. 34 | Ex. 35 |
| 1 | 0.973 | 0.865 | 0.499 | 0.426 | 0.491 | 0.596 | 0.299 | 0.559 | 0.396 | 0.137 |
| 2 | 0.743 | 0.783 | 0.722 | 0.725 | 0.760 | 1.426 | 0.345 | 0.409 | 0.482 | 0.260 |
| 3 | 0.855 | 0.824 | 0.961 | 0.802 | 1.096 | 1.345 | 0.228 | 0.098 | 0.028 | 0.024 |
| 4 | 0.713 | 1.006 | 0.789 | 0.817 | 1.147 | 1.385 | 0.201 | 0.118 | −0.037 | −0.014 |
| 5 | 0.573 | 0.827 | 0.845 | 0.542 | 0.899 | 1.196 | −0.086 | 0.010 | 0.046 | −0.179 |
| 6 | 0.799 | 0.549 | 0.761 | 0.698 | 1.154 | 1.439 | −0.237 | −0.151 | −0.314 | 0.079 |
| 7 | 0.679 | 0.988 | 0.881 | 0.549 | 1.181 | 1.214 | −0.254 | −0.060 | −0.341 | 0.049 |
| 8 | 0.666 | 0.715 | 0.410 | 0.266 | 1.117 | 1.332 | 0.072 | 0.056 | 0.096 | 0.021 |
| 9 | 0.729 | 0.594 | 0.427 | 0.020 | 1.112 | 1.161 | 0.184 | 0.112 | −0.081 | 0.116 |
| 10 | 0.700 | 0.761 | 0.690 | 0.240 | 1.296 | 1.287 | −0.130 | −0.038 | 0.028 | 0.095 |
| 15 | 0.858 | 1.045 | 0.982 | 0.371 | 1.090 | 0.364 | −0.183 | −0.079 | 0.058 | 0.008 |
| 20 | 0.886 | 0.753 | 0.773 | 0.396 | 1.091 | 1.414 | 0.172 | −0.157 | 0.061 | −0.007 |
| 25 | 0.731 | 0.566 | 0.831 | 0.458 | 1.125 | 1.214 | −0.108 | 0.163 | 0.153 | 0.048 |
| 30 | 0.694 | 0.625 | 1.181 | 0.543 | 1.544 | 1.569 | −0.020 | −0.070 | 0.122 | 0.025 |
| 35 | 0.480 | 0.786 | 0.787 | 0.713 | 1.654 | 1.327 | −0.060 | −0.189 | −0.084 | −0.184 |
| 40 | 0.819 | 0.566 | 1.179 | 0.678 | 1.449 | 1.712 | 0.110 | 0.076 | −0.399 | 0.030 |
| 45 | 1.160 | 0.594 | 0.870 | 0.741 | 1.420 | 1.489 | 0.202 | 0.150 | −0.070 | −0.145 |
| 50 | 1.311 | 0.743 | 1.072 | 0.879 | 1.533 | 1.557 | 0.356 | 0.420 | 0.245 | −0.077 |
| 60 | 1.214 | 0.599 | 0.928 | 0.705 | 1.926 | 1.817 | 0.363 | 0.444 | 0.413 | −0.240 |

### Examples 35-39

### Control of Feature Broadening in 1-60 μm Wide Feature Pattern with Different Leveler Concentration

A silicon wafer coated with a 20 nm Ti adhesion layer and a 200 nm conductive Cu seed was laminated with a PR layer with a thickness of 3 μm. A fine line pattern was built on the PR layer to contain a series of trenches ranging from 1 to 60 μm in width. These trenches were then plated to a target height of 6 μm using 5 different plating bath formulations that differed in the concentration of the leveler additive:
50 g/L Cu(II) ion
100 g/L H₂SO₄
50 ppm Chloride ion
40 ppm Bis-Sodium-Sulfopropyl-Disulfide
2 g/L Reverse Tetronic with sulfonated end groups, MW 4,800
Example 35: 0.1 ppm reaction product of butyldiglycidylether, imidazole and phenylimidazole
Example 36: 1 ppm reaction product of butyldiglycidylether, imidazole and phenylimidazole
Example 37: 2 ppm reaction product of butyldiglycidylether, imidazole and phenylimidazole
Example 38: 5 ppm reaction product of butyldiglycidylether, imidazole and phenylimidazole
Example 39: 10 ppm reaction product of butyldiglycidylether, imidazole and phenylimidazole
   Each sample was rinsed with DI water prior to plating. In all cases, galvanostatic plating was carried out at 2 ASD with a cathode rotation rate of 50 rpm. Following plating, the PR was removed in a PR stripper bath to yield a pattern of fine lines. The samples were then exposed to a seed etch solution to remove the remaining conductive seed that had been protected by the PR. Finally, the width of the plated lines was determined via laser profilometry.

The results are disclosed in Table 7 showing that anisotropic plating was most pronounced as the concentration of the leveler additive decreases. Best results in terms of minimizing plated line broadening were obtained when the leveler concentration was 1 ppm or lower.

TABLE 7
Effect of Leveler Concentration on Fine-Line
Broadening (6 μm Height, 3 μm PR)

| PR Trench | | | | | |
|---|---|---|---|---|---|
| Width | Plating Line Broadening (μm) | | | | |
| (μm) | Ex. 35 | Ex. 36 | Ex. 37 | Ex. 38 | Ex. 39 |
| 1 | 0.137 | 0.882 | 0.428 | 0.934 | 0.942 |
| 2 | 0.260 | 0.331 | 0.969 | 0.827 | 0.547 |
| 3 | 0.024 | 0.402 | 0.774 | 0.641 | 0.669 |
| 4 | −0.014 | 0.402 | 0.613 | 1.755 | 2.348 |
| 5 | −0.179 | 0.439 | 0.443 | 2.174 | 2.191 |
| 6 | 0.049 | 0.274 | 0.508 | 2.269 | 3.414 |
| 7 | 0.021 | −0.215 | 0.339 | 2.44 | 4.41 |
| 8 | 0.054 | −0.197 | 1.199 | 2.095 | 5.017 |
| 9 | 0.116 | 0.168 | 1.447 | 3.01 | 6.311 |
| 10 | 0.095 | −0.136 | 1.496 | 2.632 | 6.423 |
| 15 | 0.008 | −0.049 | 0.913 | 1.803 | 5.063 |
| 20 | −0.007 | −0.04 | −0.045 | −0.41 | 4.94 |
| 25 | 0.048 | 0.22 | 0.087 | 0.958 | 4.007 |
| 30 | 0.025 | 0.08 | 0.129 | 0.661 | 0.261 |
| 35 | −0.184 | −0.068 | 0.158 | 1.426 | −0.355 |
| 40 | 0.030 | −0.104 | 0.209 | 0.797 | 0.638 |
| 45 | −0.145 | 0.455 | 0.34 | 1.252 | −0.501 |
| 50 | −0.077 | 0.237 | 0.101 | 0.676 | 0.329 |
| 60 | −0.240 | 0.359 | 0.123 | 1.261 | −1.488 |

### Examples 40-45. Control of Feature Broadening in 1-60 μm Wide Feature Pattern with Surface Pre-treatment and Different Suppressor Additives

A silicon wafer coated with a 20 nm Ti adhesion layer and a 200 nm conductive Cu seed was laminated with a PR layer with a thickness of 3 μm. A fine line pattern was built on the PR layer to contain a series of trenches ranging from 1 to 100 μm in width. These trenches were then plated to a target height of 4.5 μm using 6 different plating bath formulations that differed in the suppressor additive:
50 g/L Cu(II) ion
100 g/L H₂SO₄
50 ppm Chloride ion
2 g/L suppressor additive
Example 40: Block EO-PO MW 1,100
Example 41: Block EO-PO MW 1,950
Example 42: Reverse Tetronic MW 5,300
Example 43: Reverse Tetronic with sulfonated end groups, MW 4,800
Example 44: Random EO/PO MW 1,100
Example 45: Reverse Tetronic MW 7,250
   Each sample was first immersed in a solution of 4 g/L MES in water of either pH 0.7 or pH 5.5, and then rinsed with DI water prior to plating. In all cases, electroplating was carried out at 2 ASD with a cathode rotation rate of 50 rpm. Following plating, the PR was removed in a PR stripper bath to yield a pattern of fine lines. The samples were then exposed to Cu and Ti etch solutions to remove the remaining conductive seed that had been protected by the PR. Finally, the width of the plated lines was determined via laser profilometry.

Each sample was first immersed in a solution of 4 g/L MES in water of either pH 0.7 or pH 5.5, and then rinsed with DI water prior to plating. In all cases, electroplating was carried out at 2 ASD with a cathode rotation rate of 50 rpm. Following plating, the PR was removed in a PR stripper bath to yield a pattern of fine lines. The samples were then exposed to Cu and Ti etch solutions to remove the remaining conductive seed that had been protected by the PR. Finally, the width of the plated lines was determined via laser profilometry.

The results are outlined in Tables 8-9 showing that seed activation improved the anisotropic plating character of all suppressors. However, the same pattern was found in Examples 35-39, which did not include seed activation. Reverse Tetronic-type suppressors were most effective at minimizing line broadening, and sulfonation of the reverse Tetronic end chains resulted in the most pronounced anisotropic plating behavior.

Each sample was first immersed in a solution of 4 g/L MES in water of either pH 0.7 or pH 5.5, and then rinsed with DI water prior to plating. In all cases, electroplating was carried out at 2 ASD with a cathode rotation rate of 50 rpm. Following plating, the PR was removed in a PR stripper bath to yield a pattern of fine lines. The samples were then exposed to Cu and Ti etch solutions to remove the remaining conductive seed that had been protected by the PR. Finally, the width of the plated lines was determined via laser profilometry.

The results are shown in Tables 8-9 showing that seed activation improves the anisotropic plating character of all suppressors. However, the same patter found in Examples 35-39, which do not include seed activation, is also found here. That is, reverse Tetronic-type suppressors are most effective at minimizing line broadening, and sulfonation of the reverse Tetronic end chains results in the most pronounced anisotropic plating behavior.

TABLE 8
Effect of Suppressor on Fine-Line Broadening (12
μm Height, 3 μm PR, pH = 5.5)

| PR Trench | | | | | | |
|---|---|---|---|---|---|---|
| Width | Plating Line Broadening (μm) | | | | | |
| (μm) | Ex. 40 | Ex. 41 | Ex. 42 | Ex. 43 | Ex. 44 | Ex. 45 |
| 1 | 0.993 | 1.003 | 0.92 | 0.922 | 1.442 | 0.403 |
| 2 | 0.979 | 1.647 | 0.98 | 0.743 | 1.476 | 0.352 |
| 3 | 1.120 | 1.977 | 0.63 | 0.982 | 1.709 | 0.258 |
| 4 | 2.030 | 2.753 | 0.95 | 0.617 | 2.420 | 0.114 |
| 5 | 2.394 | 2.633 | 0.90 | 0.407 | 2.545 | 0.050 |
| 6 | 2.429 | 3.042 | 1.91 | 0.494 | 2.584 | −0.028 |
| 7 | 2.439 | 3.358 | 2.46 | 0.401 | 2.760 | 0.209 |
| 8 | 2.328 | 2.928 | 1.53 | 0.198 | 2.826 | −0.074 |
| 9 | 2.403 | 3.265 | 0.90 | 0.268 | 1.781 | −0.083 |
| 10 | 2.060 | 2.765 | 1.20 | 0.234 | 2.286 | −0.071 |
| 15 | 0.655 | 1.682 | −0.19 | −0.114 | 1.400 | 1.324 |
| 20 | 1.530 | 1.527 | −0.54 | −0.055 | 1.185 | 0.963 |
| 25 | 0.830 | 2.113 | −0.44 | 0.018 | 1.039 | 1.350 |
| 30 | −0.030 | 2.070 | −0.24 | 0.265 | 0.852 | 0.476 |
| 35 | 0.737 | 2.551 | −0.49 | −0.144 | 1.177 | 0.630 |
| 40 | 0.014 | 2.299 | −0.44 | 0.251 | 0.731 | 1.704 |
| 45 | −0.740 | 2.525 | −0.34 | 0.053 | 1.442 | 1.480 |
| 50 | 0.160 | 2.418 | −0.40 | 0.105 | 1.046 | 2.118 |
| 60 | −0.204 | 2.619 | 0.01 | 0.256 | 1.221 | 0.419 |

TABLE 9
Effect of Suppressor on Fine-Line Broadening (12
μm Height, 3 μm PR, pH = 0.7)

| PR Trench | | | | | | |
|---|---|---|---|---|---|---|
| Width | Plating Line Broadening (μm) | | | | | |
| (μm) | Ex. 40 | Ex. 41 | Ex. 42 | Ex. 43 | Ex. 44 | Ex. 45 |
| 1 | 9.845 | 12.098 | 12.62 | 9.495 | 0 | 9.888 |
| 2 | 0.549 | 2.230 | 1.24 | 1.119 | 2.113 | 0.704 |
| 3 | 0.654 | 2.263 | 1.91 | 0.889 | 1.979 | 1.366 |
| 4 | 1.111 | 2.961 | 2.06 | 0.682 | 2.405 | 2.068 |
| 5 | 2.026 | 2.748 | 2.94 | 0.463 | 2.797 | 2.298 |
| 6 | 1.939 | 3.869 | 3.39 | 0.577 | 3.184 | 2.282 |
| 7 | 2.092 | 3.914 | 3.78 | 1.101 | 3.358 | 2.771 |
| 8 | 1.812 | 3.853 | 3.58 | 1.107 | 3.392 | 2.605 |
| 9 | 1.082 | 3.848 | 4.07 | 1.069 | 3.077 | 2.549 |
| 10 | 0.548 | 3.325 | 4.46 | 1.414 | 2.813 | 2.114 |
| 15 | 0.433 | 3.239 | 1.85 | 0.822 | 1.326 | 0.998 |
| 20 | 0.968 | 2.697 | 0.75 | 0.045 | 2.858 | 1.351 |
| 25 | 0.768 | 2.951 | 0.06 | 1.093 | 1.599 | 0.196 |
| 30 | 0.319 | 2.221 | −0.04 | 0.099 | 2.147 | 0.689 |
| 35 | 0.758 | 2.615 | −0.60 | −0.065 | 1.426 | 0.440 |
| 40 | 0.343 | 2.035 | −0.64 | 0.228 | 2.474 | 0.808 |
| 45 | 0.198 | 1.232 | −0.47 | 0.948 | 1.531 | 0.112 |
| 50 | 0.015 | 1.949 | −0.45 | 0.169 | 1.783 | −0.171 |
| 60 | −0.300 | 1.249 | 1.33 | 0.586 | 0.81 | 0.700 |

### Examples 46-48

### Seed Activation Solutions with Accelerator and Wetting Agent

The impact of including a wetting agent in the activation solution to promote levelled anisotropic plating growth was tested on three different fine-line patterns of varying line width. A silicon wafer coated with a 20 nm Ti adhesion layer and a 200 nm conductive Cu seed was laminated with a PR layer with a thickness of 3 μm. A fine line pattern was built on the PR layer to contain trenches of either 7, 20 or 100 μm in width. The trenches in each pattern were then filled via copper electroplating using Plating Bath 1, Plating Bath 2 or Plating Bath 3. The samples were first immersed in a pH 0.7 solution of 4 g/L MES and 1 g/L TN-747 wetting agent in water and then rinsed with DI water prior to plating. The 7 μm fine-line pattern was plated to a line height of 9 μm (3× PR height); The 20 μm fine-line pattern was plated to a line height of 9 μm (3× PR height); and the 100 μm fine-line pattern was plated to a line height of 36 μm (12× PR height). Electroplating was carried out at 2 ASD with a cathode rotation rate of 50 rpm. Following plating, the PR was removed in a PR stripper bath to yield a pattern of fine lines. The samples were then exposed to Cu and Ti etch solutions to remove the remaining conductive seed that had been protected by the PR. The width of the isolated Cu fine-lines was determined using a laser profilometer. The results, summarized in Table 10, showed that anisotropic Plating Bath 3 prevented the line thickness from increasing beyond the width of the shorter PR trench. Isotropic Plating Bath 1 did not prevent the plating lines from fusing when plated above the height of the PR trenches, thus destroying the fine-line pattern. Plating Bath 2, which has an intermediate anisotropic behavior, showed a minor increase in fine-line width. Line fusion occurred. The wetting agent in the pretreatment solution ensured a levelled plating by allowing all portions of the exposed seed to interact with the accelerator component. Overall, the data showed that the plating bath formulations can be tuned to control the degree of plating anisotropy.

TABLE 10

| | Plating | Plating | Plating | Plating | Plating | Plating |
|---|---|---|---|---|---|---|
| | Bath 1 - | Bath 1 - | Bath 2 - | Bath 2 - | Bath 3 - | Bath 3 - |
| PR Trench | Plated Line | Plated Line | Plated Line | Plated Line | Plated Line | Plated Line |
| Width | Height | Width | Height | Width | Height | Width |
| (μm) | (μm) | (μm) | (μm) | (μm) | (μm) | (μm) |
| 7 | 9.193 | 75.978 | 7.022 | 9.439 | 9.434 | 6.659 |
| 20 | 8.890 | 81.104 | 10.046 | 21.185 | 7.687 | 19.432 |
| 100 | 16.624 | 344.988 | 11.097 | 102.414 | 37.627 | 98.203 |

### Examples 49-56

### Impact of Activator pH on Plated Feature Shape

Control of the fine-line fill shape was studied by tuning the pH of the pretreatment solution. The same fine-line pattern used in Examples 1-2 above was treated with a 4g/L MES aqueous solution with a pH of 0.7, 3, 4, 5.5, 8, 9, 13 or 14 and rinsed with DI water prior to electroplating. The Samples were then electroplated with Plating Bath 3 to a target height of 5 μm (1.66× PR height). In all cases, electroplating was carried out at 2 ASD with a cathode rotation rate of 50 rpm. Following plating, the PR was removed in a PR stripper bath to yield a pattern of fine lines. The sample was then exposed to Cu and Ti etch solutions to remove the remaining conductive seed that had been protected by the PR. The width of the isolated Cu fine-lines was determined using a laser profilometer. The results, summarized in Table 11, showed that levelled plating was possible regardless of the pH of the pretreatment solution. However, the fill shape of the fine-lines changes significantly; that is, high pH promoted dished plating shapes, while low pH promoted slightly domed shapes. A more intermediate pH (pH=4-8) leads to a more pronounced domed shape. As the data below shows, this intermediate pH range is not advantageous for accessing desired fill shapes with anisotropic plating bath formulations. Instead, by maintaining the pH range outside the intermediate range, anisotropic plating can be further tuned to reduce doming profile or induce dished profile.

TABLE 11

| | Line | Line | Line | Line | Line | Line | Line | Line |
|---|---|---|---|---|---|---|---|---|
| | Height | Height | Height | Height | Height | Height | Height | Height |
| PR trench | μm | μm | μm | μm | μm | μm | μm | μm |
| width | (Activator | (Activator | (Activator | (Activator | (Activator | (Activator | (Activator | (Activator |
| μm | pH = 0.7) | pH = 3) | pH = 4) | pH = 5.5) | pH = 8) | pH = 9) | pH = 13.3) | pH = 14) |
| 6 | 4.805 | 4.511 | 4.679 | 4.295 | 3.917 | 4.700 | 4.801 | 4.766 |
| 7 | 4.983 | 4.745 | 4.918 | 4.618 | 4.824 | 5.008 | 4.969 | 4.753 |
| 8 | 5.516 | 5.127 | 4.918 | 5.079 | 5.155 | 5.400 | 4.969 | 4.853 |
| 9 | 5.480 | 5.215 | 5.410 | 5.311 | 5.406 | 5.522 | 5.481 | 5.504 |
| 10 | 5.809 | 5.323 | 5.805 | 5.550 | 5.442 | 5.674 | 5.786 | 5.481 |
| 15 | 6.009 | 5.513 | 5.306 | 5.727 | 5.668 | 5.882 | 5.647 | 5.498 |
| 20 | 5.701 | 5.220 | 5.408 | 5.491 | 5.410 | 5.514 | 5.473 | 5.305 |
| 25 | 5.144 | 5.000 | 4.751 | 5.274 | 5.366 | 5.399 | 4.942 | 4.983 |
| 30 | 4.870 | 4.828 | 4.523 | 5.043 | 5.159 | 5.237 | 4.855 | 4.923 |
| 35 | 4.816 | 4.878 | 4.431 | 5.104 | 5.192 | 4.678 | 4.837 | 4.951 |
| 40 | 5.322 | 4.777 | 4.451 | 4.924 | 4.840 | 4.820 | 4.907 | 4.938 |
| 45 | 4.838 | 4.836 | 4.536 | 4.856 | 4.766 | 5.029 | 5.019 | 5.175 |
| 50 | 4.849 | 5.050 | 4.667 | 4.832 | 4.718 | 5.092 | 5.350 | 5.586 |
| 60 | 4.808 | 4.862 | 6.021 | 4.789 | 4.774 | 4.958 | 6.055 | 5.930 |
| 70 | 4.828 | 4.873 | 5.354 | 4.690 | 4.568 | 4.630 | 5.738 | 5.902 |
| 80 | 5.070 | 4.681 | 4.825 | 4.650 | 4.528 | 4.852 | 5.264 | 5.338 |
| 90 | 5.145 | 4.922 | 4.592 | 3.431 | 3.735 | 4.512 | 5.288 | 5.359 |
| 100 | 5.926 | 5.177 | 4.775 | 4.496 | 4.668 | 4.988 | 5.441 | 5.728 |
| Fill | Slightly | Domed | Domed | Domed | Domed | Slightly | Slightly | Slightly |
| Shape | Domed | | | | | Dished | Dished | Dished |

### Example 57-59

### Anisotropic Plating when Removing the PR Layer After Activation and Before Electrolytic Plating

The ability of anisotropic plating methodology described herein to sustain feature resolution even in the absence of a patterning layer during plating was studied. To do so, three plating scenarios were examined to test compare plating anisotropic performance with and without a PR layer versus a control isotropic run without a PR layer. The same patterned substrate from Examples 3-6 was used. Example 57 sample was pretreated with 4 g/L MES aqueous solution, rinsed with DI water and the PR layer was removed prior to plating using 1:1 dimethylsulfoxide-y-butyrolactone mixture. Example 58 sample was only pretreated with 4 g/L MES aqueous solution and rinsed with DI water. Example 59 sample was only pretreated with DI water. Examples 57-58 samples were plated with Plating Bath 3, and Example 59 sample was plated with Plating Bath 1. All three samples were plated at 2 ASD with a cathode rotation rate of 50 rpm and a plating target height of 5 μm. Following plating, the PR was removed in a Shipley BPR™ PR stripper bath to yield a pattern of fine lines. The sample was then exposed to a seed etch solution to remove the remaining conductive seed that had been protected by the PR. The width and height of the isolated Cu fine-lines was determined using a laser profilometer. The results, summarized in Table 12, showed that significant line fusion was prevented in Example 57-58 samples, wherein anisotropic plating occurred even in the absence of a patterning PR layer during plating. Example 59 sample, on the other hand, showed significant line fusion at all fine-line widths. All samples as shown in Table 13 showed good levelling of plating heights across the feature width range.

TABLE 12

| | | | | | |
|---|---|---|---|---|---|
| Target (μm) | 6 | 7 | 30 | 50 | 80 |
| Measured (μm) | 8 | 9 | 32 | 55 | 81 |
| Ex. 57 | | | | | |
| Measured (μm) | 6 | 7 | 30 | 50 | 80 |
| Ex. 58 | | | | | |
| Measured (μm) | Fused | Fused | Fused | Fused | Fused |
| Ex. 59 | | | | | |

TABLE 13

| | Example 57 | Example 58 | Example 59 |
|---|---|---|---|
| | PR OFF | PR ON | PR OFF |
| PR Trench | Plated Line | Plated Line | Plated Line |
| Width | Height | Height | Height |
| (μm) | (μm) | (μm) | (μm) |
| 1 | 5.897 | 5.255 | 2.660 |
| 2 | 4.046 | 6.429 | 3.795 |
| 3 | 3.862 | 6.605 | 4.639 |
| 4 | 4.198 | 6.524 | 5.333 |
| 5 | 4.820 | 4.483 | 5.941 |
| 6 | 5.401 | 4.073 | 6.552 |
| 7 | 5.704 | 4.388 | 6.938 |
| 8 | 6.317 | 4.869 | 7.469 |
| 9 | 6.468 | 5.122 | 7.703 |
| 10 | 6.703 | 5.421 | 8.212 |
| 15 | 6.776 | 6.094 | 9.403 |
| 20 | 6.858 | 6.342 | 10.140 |
| 25 | 6.375 | 6.262 | 10.410 |
| 30 | 6.177 | 6.342 | 10.464 |
| 35 | 5.942 | 6.265 | 10.367 |
| 40 | 5.656 | 6.210 | 10.176 |
| 45 | 5.496 | 6.146 | 12.203 |
| 50 | 5.760 | 6.104 | 7.687 |
| 60 | 6.764 | 6.103 | 9.972 |
| 70 | 5.666 | 6.135 | 11.758 |
| 80 | 6.679 | 6.131 | 10.910 |
| 90 | 6.765 | 6.156 | 9.814 |
| 100 | 5.778 | 4.830 | 10.781 |

What is claimed is:

1. A method comprising:
a) providing a substrate comprising a seed layer;
b) optionally selectively applying an aqueous treatment solution comprising a sulfur containing accelerator to the seed layer, wherein a pH of the aqueous treatment solution is below 3, or above 9;
c) providing a copper electroplating composition comprising a source of copper ions, an accelerator, an acid, a source of chloride, a suppressor which generates an α-peak curve in a cathode wave of a voltammogram of the copper electroplating composition on a working electrode, and a leveler, wherein the leveler is a copolymer of a reaction product of imidazole and butyldiglycidyl ether or a copolymer of a reaction product of imidazole and phenylimidazole;
d) contacting the substrate comprising the seed layer with the copper electroplating composition; and
e) anisotropically electroplating copper on the seed layer of the substrate.

2. The method of claim 1, wherein the suppressor which generates an α-peak curve in a cathode wave of the voltammogram is selected from the group consisting of polyethylene glycols having a weight average molecular weight of 1000-6000 g/mol.

3. The method of claim 1, wherein the suppressor which generates an α-peak curve in a cathode wave of the voltammogram is selected from the group consisting of EO/PO block copolymers having a weight average molecular weight of 1000-5000 g/mol.

4. The method of claim 1, wherein the suppressor which generates an α-peak curve in a cathode wave of the voltammogram is selected from the group consisting of EO/PO random copolymers having a weight average molecular weight of 1000-5000 g/mol.

5. The method of claim 1 wherein the suppressor which generates an α-peak curve in a cathode wave of the voltammogram is selected from the group consisting of diamine core EO/PO block copolymers

6. The method of claim 5, wherein the diamine core EO/PO block copolymer has the formula: 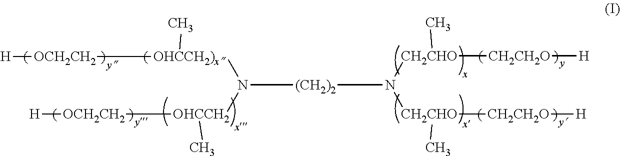
wherein a molecular weight ranges from 1000-10000 g/mol and variables x, x″. x″, x″′, y, y′, y″ and y″′ are integers greater than or equal to 1 to provide the molecular weight range of 1000-10,000 g/mol.

7. The method of claim 5, wherein the diamine core EO/PO block copolymer has the formula: 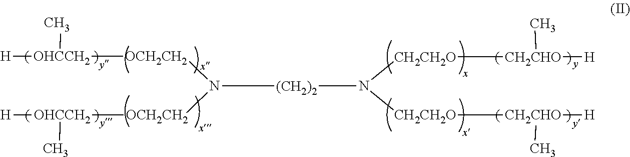
wherein a molecular weight ranges from 1000-10000 g/mol and variables x, x″. x″, x″′, y, y′, y″ and y″′ are integers greater than or equal to 1 to provide the molecular weight range of 1000-10,000 g/mol.

8. The method of claim 5, wherein the diamine core EO/PO block copolymer has the formula: 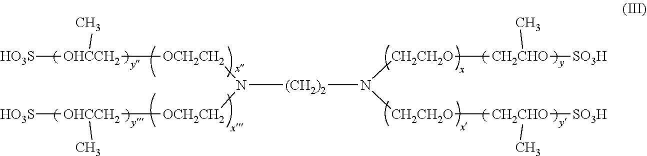
wherein a molecular weight ranges from 1000-10000 g/mol and variables x, x″. x″, x″, y, y′, y″ and y″′ are integers greater than or equal to 1 to provide the molecular weight range of 1000-10,000 g/mol.

9. A method comprising:
a) providing a substrate comprises a seed layer;
b) coating the seed layer with photoresist;
c) imaging the photoresist to form a pattern on the substrate and selectively expose seed layer;
d) optionally applying an aqueous treatment solution comprising a sulfur containing accelerator to the exposed seed layer, wherein the aqueous treatment solution has a pH below 3, or a pH above 9;
e) providing a copper electroplating composition comprising a source of copper ions, an accelerator, an acid, a source of chloride, a suppressor which generates an α-peak curve in a cathode wave of a voltammogram of the copper electroplating composition on a working electrode, and a leveler, wherein the leveler is a copolymer of a reaction product of imidazole and butyldiglycidyl ether or a copolymer of a reaction product of imidazole and phenylimidazole;
f) contacting the substrate comprising the seed layer with the anisotropic copper electroplating composition; and
g) electroplating anisotropic copper on the seed layer of the substrate.

10. An article comprising a copper deposit at least 2 μm above a height of a surrounding photoresist and comprises incoherent boundaries orientated at 80-90° relative to a plane of a substrate and comprises concurrent twinned boundaries orientated at 40-50° relative to the plane of the substrate.
